(19) United States
(12) Patent Application Publication
(10) Pub. No.: US 2026/0344239 A1
(43) Pub. Date: Oct. 29, 2026

(54) DISPLAY DEVICE

(71) Applicant: LG Display Co., Ltd., Seoul (KR)

(72) Inventors: Seongsoo CHO, Paju-si (KR); Woosung Kim, Paju-si (KR); Hyunseok NA, Paju-si (KR); Sanghak Shin, Paju-si (KR)

(21) Appl. No.: 19/660,176

(22) Filed: Apr. 27, 2026

(30) Foreign Application Priority Data
Apr. 28, 2025 (KR) 10-2025-0055110

(51) Int. Cl. H10K 59/38; H10K 59/121; H10K 59/80

(52) U.S. Cl. CPC H10K 59/38; H10K 59/1213; H10K 59/8792

(57) ABSTRACT

A display device includes a substrate on which a first sub-pixel and a fourth sub-pixel of a first pixel are defined, a 1a transistor and a 1d transistor on the substrate, and a first light-emitting element connected to the 1a transistor and disposed on the first sub-pixel, and a fourth light-emitting element connected to the 1d transistor and disposed on the fourth sub-pixel, in which each of the first light-emitting element and the fourth light-emitting element includes an inorganic light-emitting element, first light or third light is emitted from the first sub-pixel, second light or the third light is emitted from the fourth sub-pixel, each of the 1a transistor and the 1d transistor is a driving transistor, and a width of a 1a semiconductor layer of the 1a transistor is greater than a width of a 1d semiconductor layer of the 1d transistor.

### CROSS REFERENCE TO RELATED APPLICATION

This application claims priority from and the benefit of Korean Patent Application No. 10-2025-0055110, filed on Apr. 28, 2025, which is hereby incorporated by reference for all purposes as if fully set forth herein.

### BACKGROUND

### Field

Embodiments of the invention relate to a display device.

### Discussion of the Background

Liquid crystal display (LCD) displays, organic light-emitting (OLED) display devices, and quantum dot display devices (QDs), which are widely used today, are gradually expanding their range of application.

Display devices implement an image by arranging a plurality of light-emitting elements on a substrate of the display device and by arranging, on the same substrate, driving elements that supply driving signals or driving current to individually control light emission of each light-emitting element. Accordingly, the plurality of light-emitting elements disposed on the substrate are driven according to the arrangement of information to be displayed, thereby displaying the information on the substrate.

LCDs are not self-luminous and therefore require a backlight unit disposed to emit light from a rear surface thereof. The backlight unit may increase the thickness of the LCD, limit implementation of various display forms, such as flexible, circular, and the like, and reduce luminance and response time.

Meanwhile, display devices having self-emissive elements can be thinner than display devices with built-in light sources, thereby enabling flexible and foldable display devices. Such display devices may include an OLED display device including organic materials as a light-emitting layer, light-emitting diode (LED) display devices using LEDs as the light-emitting elements, and the like. Because self-luminous display devices, such as OLED display devices and LED display devices, do not require a separate light source, they can provide reduced thickness and a wider range of display formats.

However, because OLED display devices that use organic materials are prone to defective pixels caused by issues such as oxidation between the organic light-emitting layer and the electrodes due to moisture and oxygen penetration, various technical configurations are required to minimize such penetration.

Recently, research and development on display devices using inorganic LEDs as light-emitting elements has been actively conducted, and such light-emitting display devices are attracting attention as next-generation displays due to their high image quality and high reliability.

The above information disclosed in this Background section is only for understanding of the background of the inventive concepts, and, therefore, it may contain information that does not constitute prior art.

### SUMMARY

Embodiments of the invention provide a display device capable of repairing a pixel by repairing a color conversion layer.

Embodiments of the invention provide a display device capable of improving an image quality of a display panel by repairing a pixel.

Embodiments of the invention provide a display device capable of achieving low power consumption by repairing a sub-pixel.

Embodiments of the invention provide a display device capable of optimizing a structure of each sub-pixel based on required current in the display device to which the sub-pixel repair may be applied.

Additional features of the inventive concepts will be set forth in the description which follows, and in part will be apparent from the description, or may be learned by practice of the inventive concepts.

According to an embodiment of the invention, a display device includes a first pixel including a first sub-pixel, a second sub-pixel, a third sub-pixel, and a fourth sub-pixel, a black matrix disposed on at least one of the first sub-pixel to the fourth sub-pixel of the first pixel; and a second pixel disposed adjacent to the first pixel including a first sub-pixel, a second sub-pixel, a third sub-pixel, and a fourth sub-pixel, in which in the first pixel, a first color conversion layer is disposed on the first sub-pixel, a second color conversion layer is disposed on the second sub-pixel, a third color conversion layer is disposed on the third sub-pixel, and a fourth color conversion layer is disposed on the fourth sub-pixel, and in which in the second pixel, a color conversion layer different from the first, second, third, and fourth color conversion layers is disposed on at least one of the first sub-pixel, the second sub-pixel, the third sub-pixel, and the fourth sub-pixel.

In the first pixel, the black matrix may be disposed on the first sub-pixel and the second sub-pixel, and in the second pixel, the third color conversion layer may be disposed on the first sub-pixel and the first color conversion layer may be disposed on the third sub-pixel.

In the first pixel, the black matrix may be disposed on the first sub-pixel and the fourth sub-pixel, and in the second pixel, the third color conversion layer may be disposed on the first sub-pixel and the first color conversion layer may be disposed on the third sub-pixel.

In the first pixel, the black matrix may be disposed on the third sub-pixel and the fourth sub-pixel, and in the second pixel, the third color conversion layer may be disposed on the first sub-pixel and the first color conversion layer may be disposed on the third sub-pixel.

In the first pixel, the black matrix may be disposed on the second sub-pixel and the third sub-pixel, and in the second pixel, the third color conversion layer may be disposed on the first sub-pixel and the first color conversion layer may be disposed on the third sub-pixel.

According to another embodiment of the invention, a display device includes a first pixel including a first sub-pixel, a second sub-pixel, a third sub-pixel, a fourth sub-pixel, and a black matrix disposed on at least one of the first sub-pixel to the fourth sub-pixel, in which a color conversion layer of the at least one of the first sub-pixel to the fourth sub-pixel on which the black matrix is disposed is further disposed on a remaining one of the at least one of the first sub-pixel to the fourth sub-pixel on which the black matrix is not disposed.

The black matrix may be disposed on the first sub-pixel, and the color conversion layer of the first sub-pixel may be further disposed on the second sub-pixel.

The black matrix may be disposed on the third sub-pixel, and a color conversion layer of the third sub-pixel may be further disposed on the fourth sub-pixel.

According to an embodiment of the invention, a display device includes a substrate including a first pixel comprising a first sub-pixel and a fourth sub-pixel, a 1a transistor and a 1d transistor disposed on the substrate, and a first light-emitting element electrically connected to the 1a transistor and disposed on the first sub-pixel, and a fourth light-emitting element electrically connected to the 1d transistor and disposed on the fourth sub-pixel, in which each of the first light-emitting element and the fourth light-emitting element includes an inorganic light-emitting element, the first sub-pixel is configured to emit first light or third light, the fourth sub-pixel is configured to emit second light or third light, each of the 1a transistor and the 1d transistor includes a driving transistor, and a width of a 1a semiconductor layer of the 1a transistor is greater than a width of a 1d semiconductor layer of the 1d transistor.

A length of the 1a semiconductor layer may be the same as a length of the 1d semiconductor layer.

The 1a transistor may further include a 1a gate electrode disposed on the 1a semiconductor layer, the 1d transistor may further include a 1d gate electrode disposed on the 1d semiconductor layer, and a width of the 1a gate electrode may be greater than a width of the 1d gate electrode.

The display device may further include a 2a transistor electrically connected to the 1a gate electrode; and a 2d transistor electrically connected to the 1d gate electrode, in which a width of a 2a semiconductor layer of the 2a transistor is the same as a width of a 2d semiconductor layer of the 2d transistor.

A length of the 2a semiconductor layer may be the same as a length of the 2d semiconductor layer.

Each of the 2a transistor and the 2d transistor may include a switching transistor.

The display device may further include a second sub-pixel defined on the substrate; a 1b transistor disposed on the substrate; and a second light-emitting element electrically connected to the 1b transistor and disposed on the second sub-pixel, in which the second light-emitting element includes the inorganic light-emitting element, the second sub-pixel is configured to emit a green light or a red light, the 1b transistor includes the driving transistor, and a width of a 1b semiconductor layer of the 1b transistor is greater than a width of the 1d semiconductor layer.

The width of the 1b semiconductor layer may be the same as the width of the 1a semiconductor layer.

The length of the 1b semiconductor layer may be the same as the length of the 1a semiconductor layer.

The second sub-pixel may be disposed at a left side of the first sub-pixel in a plan view, and the fourth sub-pixel may be disposed below the first sub-pixel in a plan view.

The display device may further include a second sub-pixel, in which a current required for driving the first sub-pixel may be higher than a current required for driving the second sub-pixel and a current required for driving the fourth sub-pixel.

The display device may further include a third sub-pixel, in which a current required for driving the first sub-pixel may be higher than a current required for driving the second sub-pixel and a current required for driving the fourth sub-pixel, and in which the current required for driving the second sub-pixel may be higher than a current required for driving the third sub-pixel.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the inventive concepts.

FIG. 1 is a system configuration diagram of a display device according to an embodiment of the invention.

FIG. 2 is a diagram illustrating a sub-pixel according to an embodiment of the invention.

FIG. 3 is a diagram illustrating a first-type conversion between sub-pixels within a pixel according to an embodiment of the invention.

FIG. 4 is a diagram illustrating a repair to which the first-type conversion in FIG. 3 is applied.

FIG. 5 is a cross-sectional view taken along line A-A’ of FIG. 4.

FIG. 6 is a cross-sectional view taken along line B-B’ of FIG. 4.

FIG. 7 is a cross-sectional view taken along line C-C’ of FIG. 4.

FIG. 8 is a diagram illustrating a repair to which the first-type conversion in FIG. 3 is applied.

FIG. 9 is a diagram illustrating a repair to which the first-type conversion in FIG. 3 is applied.

FIG. 10 is a diagram illustrating a repair to which the first-type conversion in FIG. 3 is applied.

FIG. 11 is a diagram illustrating a second-type conversion between sub-pixels within a pixel according to an embodiment of the invention.

FIG. 12 is a diagram illustrating a repair to which the second-type conversion in FIG. 11 is applied.

FIG. 13 is a cross-sectional view taken along line D-D’ of FIG. 12.

FIG. 14 is a diagram illustrating a third-type conversion between sub-pixels within a pixel according to an embodiment of the invention.

FIG. 15 is a diagram illustrating a repair to which the third-type conversion in FIG. 14 is applied.

FIG. 16 is a cross-sectional view taken along line E-E’ of FIG. 15.

FIG. 17 is a layout diagram of a pixel according to an embodiment of the invention.

FIG. 18 is a cross-sectional view of a first sub-pixel in FIG. 17.

FIG. 19 is a cross-sectional view of a fourth sub-pixel in FIG. 17.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the D1-axis, the D2-axis, and the D3-axis are not limited to three axes of a rectangular coordinate system, such as the x, y, and z – axes, and may be interpreted in a broader sense. For example, the D1-axis, the D2-axis, and the D3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

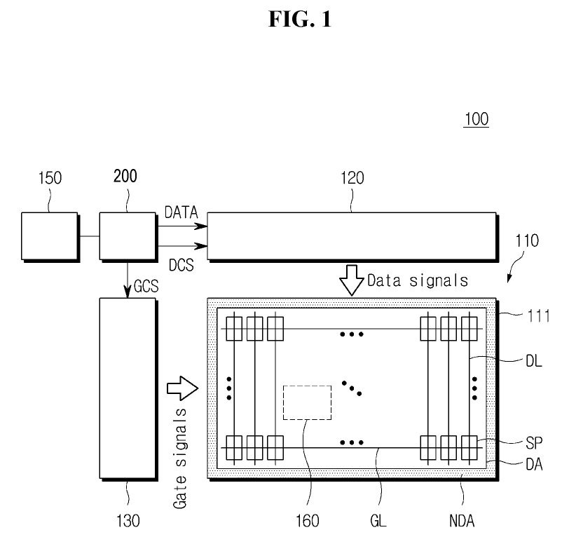

FIG. 1 is a system configuration diagram of a display device according to an embodiment of the invention.

Referring to FIG. 1, a display device 100 may include components for displaying images, such as a display panel 110 and a display driving circuit. The display driving circuit may drive the display panel 110 and include a data driving circuit 120, a gate driving circuit 130, a display controller 200, etc.

The display panel 110 may include a substrate 111 and a plurality of sub-pixels SP disposed on the substrate 111. The substrate 111 of the display panel 110 may include a display area DA capable of displaying images and a non-display area NDA positioned outside the display area DA.

The plurality of sub-pixels SP for displaying images may be disposed in the display area DA.

In the display panel 110 according to embodiments of the invention, the non-display area NDA may be very small. As used herein, the non-display area NDA may also be referred to as a “bezel.”

Various types of signal lines for driving the plurality of sub-pixels SP may be disposed on the substrate 111 of the display panel 110.

The display device 100 according to embodiments of the invention may be a liquid crystal display device, a self-emissive display device in which the display panel 110 emits light by itself, or the like. When the display device 100 according to embodiments of the invention is a self-emissive display device, each of the plurality of sub-pixels SP may include a light-emitting element. For example, the display device 100 according to embodiments of the invention may be an organic light-emitting display device in which the light-emitting element is implemented as an organic light-emitting diode (OLED). As another example, the display device 100 according to embodiments of the invention may be an inorganic light-emitting display device in which a light-emitting element is implemented as an inorganic material-based light-emitting diode. As still another example, the display device 100 according to embodiments of the invention may be a quantum dot display device in which the light-emitting element is implemented as quantum dots that are semiconductor crystals that emits light by themselves. However, embodiments of the invention are not limited thereto.

The structure of each of the plurality of sub-pixels SP may vary depending on the type of the display device 100. For example, when the display device 100 is a self-emissive display device in which the sub-pixels SP emit light by themselves, each sub-pixel SP may include a light-emitting element that emits light by itself, one or more transistors, and one or more capacitors.

For example, various types of signal lines may include a plurality of data lines DL through which data signals (also referred to as data voltages or image signals) are transmitted, a plurality of gate lines GL through which gate signals (also referred to as scan signals) are transmitted, etc.

The data driving circuit 120 may drive the plurality of data lines DL and output data signals to the plurality of data lines DL. The data driving circuit 120 may receive digital image data DATA from the display controller 200, convert the received image data DATA into analog data signals, and output the analog data signals VDATA to the plurality of data lines DL. The data driving circuit 120 may be connected to one side (upper side or lower side) of the display panel 110. Alternatively, the data driving circuit 120 may be connected to both sides (e.g., the upper and lower sides) of the display panel 110 or connected to two or more of four side surfaces of the display panel 110 according to a driving method, a panel design method, etc. The data driving circuit 120 may be connected to an outer edge of the display area DA of the display panel 110, but alternatively, may be disposed inside the display area DA of the display panel 110.

The gate driving circuit 130 may drive the plurality of gate lines GL and output gate signals to the plurality of gate lines GL. The gate driving circuit 130 may receive a first gate voltage corresponding to a turn-on level voltage and a second gate voltage corresponding to a turn-off level voltage together with various gate driving control signals GCS, generate the gate signals, and supply the generated gate signals to the plurality of gate lines GL.

The display controller 200 may control the data driving circuit 120 and the gate driving circuit 130 and control the driving timing for the plurality of data lines DL and the driving timing for the plurality of gate lines GL. The display controller 200 may supply a data driving control signal DCS to the data driving circuit 120 to control the data driving circuit 120 and supply the gate driving control signal GCS to the gate driving circuit 130 to control the gate driving circuit 130. The display controller 200 may receive input image data from a host system 150 and supply the image data DATA to the data driving circuit 120 based on the input image data. The display controller 200 may be implemented as a component separately from the data driving circuit 120 or implemented as an integrated circuit with the data driving circuit 120. The display controller 200 may be a timing controller used in a typical display technology, a control device capable of further performing other control functions in addition to the timing controller, a control device different from the timing controller, or a circuit in the control device. The display controller 200 may be mounted on a printed circuit board, a flexible printed circuit, etc., and electrically connected to the data driving circuit 120 and the gate driving circuit 130 through the printed circuit board, the flexible printed circuit, etc.

To provide both an image display function and a touch sensing function, the display device 100 according to embodiments of the invention may include a touch sensor and a touch sensing circuit to detect whether touch is caused by a touch object, such as a finger, a pen, etc., or to detect a touch position by sensing the touch sensor.

The display device 100 according to embodiments of the invention may further include electronic devices, such as a camera (image sensor), a detection sensor, etc. For example, the detection sensor may detect an object or human body by receiving light, such as infrared rays, ultrasonic waves, ultraviolet rays, etc.

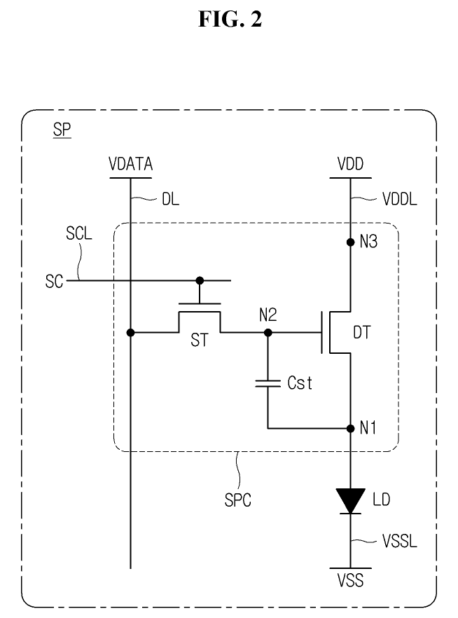

FIG. 2 is a diagram illustrating a sub-pixel according to an embodiment of the invention.

Referring to FIG. 2, each of the plurality of sub-pixels SP may include a light-emitting element LD and a sub-pixel circuit SPC for driving the light-emitting element LD.

Referring to FIG. 2, the sub-pixel circuit SPC may include a plurality of pixel driving transistors and at least one capacitor for driving a light-emitting element LD.

According to this embodiment, the sub-pixel circuit SPC may drive the light-emitting element LD by supplying driving current to the light-emitting element LD at a predetermined timing. The light-emitting element LD may be driven by the driving current to emit light.

The plurality of pixel driving transistors may include a driving transistor DT for driving the light-emitting element LD and a scan transistor ST that is turned on or off according to a scan signal SC.

The driving transistor DT may supply the driving current to the light-emitting element LD.

The scan transistor ST may be configured to control an electrical state of a corresponding node within the sub-pixel circuit SPC or control a state or operation of the driving transistor DT.

At least one capacitor may include a storage capacitor Cst for maintaining a predetermined voltage for a frame.

In order to drive the sub-pixel SP, a data signal VDATA, which is an image signal, and the scan signal SC, which is a gate signal, may be applied to the sub-pixel SP. In addition, in order to drive the sub-pixel SP, a common pixel driving voltage including a driving voltage VDD, a base voltage VSS, etc. may be applied to the sub-pixel SP.

The light-emitting element LD may be an OLED, an inorganic material-based LED, a quantum dot light-emitting element, etc. For example, when the light-emitting element LD is the OLED, a light-emitting element intermediate layer EL of the light-emitting element LD may include an organic material-containing light-emitting element intermediate layer EL.

The driving transistor DT may supply driving current to the light-emitting element LD. The driving transistor DT may be connected to a driving voltage line VDDL and the light-emitting element LD. The driving transistor DT may include a first node N1 electrically connected to the light-emitting element LD, a second node N2 to which the data signal VDATA may be applied, and a third node N3 to which the driving voltage VDD is applied from the driving voltage line VDDL. In the driving transistor DT, the second node N2 may be a gate node, the first node N1 may be a source node or a drain node, and the third node N3 may be a drain node or a source node. Hereinafter, for convenience of description, an example in which, in the driving transistor DT, the second node N2 is a gate node, the first node N1 is a source node, and the third node N3 is a drain node will be described.

The scan transistor ST included in the sub-pixel circuit SPC illustrated in FIG. 2 may be a switching transistor for transmitting the data signal VDATA, which is an image signal, to the second node N2, which is the gate node of the driving transistor DT. The scan transistor ST may be turned on and off by the scan signal SC, which is the gate signal applied through a scan line SCL, which is a type of gate line GL, thereby controlling electrical connection between the second node N2 of the driving transistor DT and the data line DL. A drain electrode or source electrode of the scan transistor ST may be electrically connected to the data line DL, the source electrode or drain electrode of the scan transistor ST may be electrically connected to the second node N2 of the driving transistor DT, and the gate electrode of the scan transistor ST may be electrically connected to the scan line SCL.

The storage capacitor Cst may be electrically connected to the first node N1 and the second node N2 of the driving transistor DT. The storage capacitor Cst may include a first capacitor electrode electrically connected to or corresponding to the first node N1 of the driving transistor DT, and a second capacitor electrode electrically connected to or corresponding to the second node N2 of the driving transistor DT. The storage capacitor Cst may be an external capacitor intentionally designed outside the driving transistor DT, rather than parasitic capacitors (e.g., Cgs, Cgd) that are internal capacitors, which may be present between the first node N1 and the second node N2 of the driving transistor DT.

Each of the driving transistor DT and the scan transistor ST may be an n-type transistor or a p-type transistor.

The display panel 110 may have a top emission structure or a bottom emission structure. When the display panel 110 has the top emission structure, at least a portion of the sub-pixel circuit SPC may vertically overlap at least a portion of the light-emitting element LD. Alternatively, when the display panel 110 has the bottom emission structure, the sub-pixel circuit SPC may not vertically overlap the light-emitting element LD.

As illustrated in FIG. 2, the sub-pixel circuit SPC may have a 2T (transistor) 1C (capacitor) structure including two transistors DT and ST and one capacitor Cst, and in some cases, may further include one or more transistors or one or more capacitors. For example, the sub-pixel circuit SPC may have an 8T1C structure including eight transistors and one capacitor. As another example, the sub-pixel circuit SPC may have a 6T2C structure including six transistors and two capacitors. As still another example, the sub-pixel circuit SPC may have a 7T1C structure including seven transistors and one capacitor. However, embodiments of the invention are not limited thereto.

Depending on the structure of the sub-pixel circuit SPC, the type and number of gate signal lines supplied to the sub-pixel SP may vary. In addition, depending on the structure of the sub-pixel circuit SPC, the type and number of common pixel driving voltage supplied to the sub-pixel SP may vary.

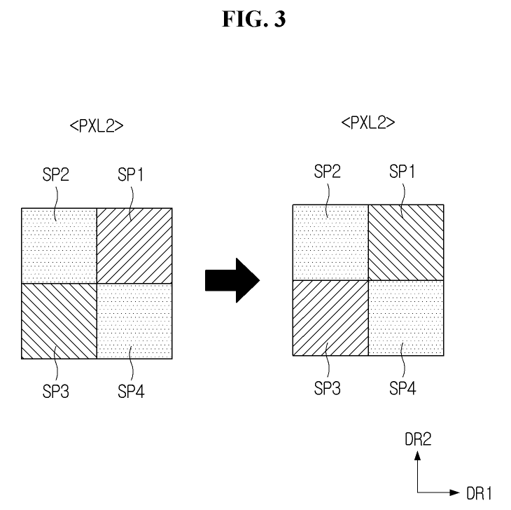

FIG. 3 is a diagram illustrating a first-type conversion between sub-pixels within a pixel according to an embodiment of the invention. As used herein, conversion may refer to light emission in which, in sub-pixels subject to conversion, an originally intended emission color is converted into a color intended to be emitted from an adjacent different sub-pixel. As will be described below, the first-type conversion may be a conversion of a first sub-pixel and a third sub-pixel, a second-type conversion may be a conversion of the first sub-pixel and a second sub-pixel, and a third-type conversion may be a conversion of a fourth sub-pixel and the third sub-pixel.

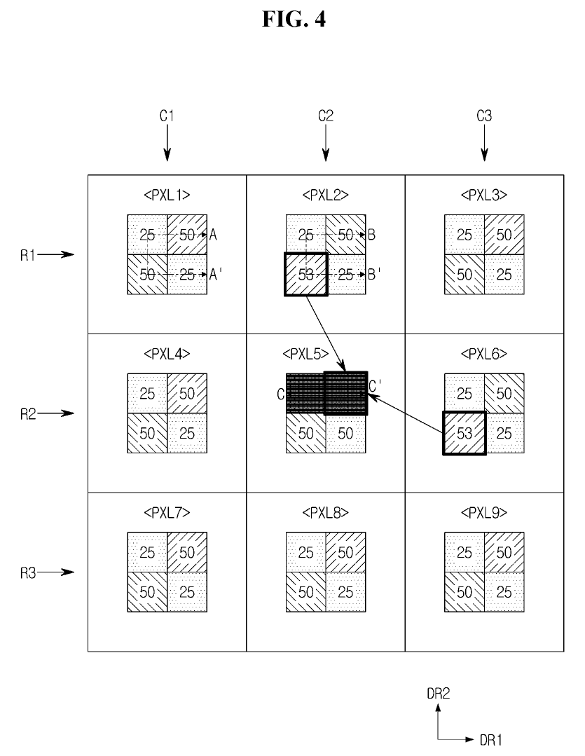

FIG. 3 illustrates sub-pixels of a second pixel PXL2 in FIG. 4. The left drawing of FIG. 3 illustrates the second pixel PXL2 before the first-type conversion is applied, and the right drawing of FIG. 3 illustrates the second pixel PXL2 to which the first-type conversion is applied.

Each of pixels in FIG. 4 may include a first sub-pixel SP1, a second sub-pixel SP2, a third sub-pixel SP3, and a fourth sub-pixel SP4. The first sub-pixel SP1 may be disposed on one side in a second direction DR2 and one side in a first direction DR1, the second sub-pixel SP2 may be disposed on one side in the second direction DR2 and the other side in the first direction DR1, the third sub-pixel SP3 may be disposed on the other side in the second direction DR2 and the other side in the first direction DR1, and the fourth sub-pixel SP4 may be disposed on the other side in the second direction DR2 and one side in the first direction DR1. For example, the first sub-pixel SP1 may be disposed at an upper right, the second sub-pixel SP2 may be disposed at an upper left, the third sub-pixel SP3 may be disposed at a lower left, and the fourth sub-pixel SP4 may be disposed at a lower right.

The four sub-pixels SP1 to SP4 may constitute one pixel PXL. By adjusting a grayscale of each of the four sub-pixels SP1 to SP4, a grayscale and color of one pixel PXL may be controlled.

The four sub-pixels SP1 to SP4 may be a combination of RGGB, BRRG, RBBG, RGBW, RGBY, WYYW, RYYW, etc. R denotes red, G denotes green, B denotes blue, W denotes white, and Y denotes yellow. The above combinations may further include M (magenta) and C (cyan). For convenience of description, the following description assumes that the four sub-pixels SP1 to SP4 are RGGB.

As illustrated in the left drawing of FIG. 3, the first sub-pixel SP1 may emit red light, the second sub-pixel SP2 may emit green light, the third sub-pixel SP3 may emit blue light, and the fourth sub-pixel SP4 may emit green light.

As illustrated in the right drawing of FIG. 3 to which the first-type conversion is applied, the color of light emitted from each of the first sub-pixel SP1 and the third sub-pixel SP3 may be changed. More particularly, blue light may be emitted from the first sub-pixel SP1, and red light may be emitted from the third sub-pixel SP3.

FIG. 4 is a diagram illustrating a repair to which the first-type conversion in FIG. 3 is applied.

Referring to FIG. 4, a plurality of pixels PXL may be disposed in a matrix form.

The first pixel PXL1 to the third pixel PXL3 may be disposed in a first row R1. The first pixel PXL1 to the third pixel PXL3 may be disposed in a first column C1, a second column C2, and a third column C3, respectively.

A fourth pixel PXL4 to a sixth pixel PXL6 may be disposed in a second row R2. The fourth pixel PXL4 to the sixth pixel PXL6 may be disposed in the first column C1, the second column C2, and the third column C3, respectively.

A seventh pixel PXL7 to a ninth pixel PXL9 may be disposed in a third row R3. The seventh pixel PXL7 to the ninth pixel PXL9 may be disposed in the first column C1, the second column C2, and the third column C3, respectively.

Each of the plurality of pixels PXL1 to PXL9 may include the four sub-pixels SP1 to SP4 (see FIG. 3). FIG. 4 illustrates grayscales of the four sub-pixels SP1 to SP4 (see FIG. 3) included in each of the plurality of pixels PXL1 to PXL9. In each of the sub-pixels of FIG. 4, for example, a 50 grayscale level may be represented in the first sub-pixel SP1, a 25 grayscale level may be represented in the second sub-pixel SP2, the 50 grayscale level may be represented in the third sub-pixel SP3, and the 25 grayscale level may be represented in the fourth sub-pixel SP4 (excluding PXL2, PXL5, PXL6). However, embodiments of the invention are not limited thereto.

In an embodiment of FIG. 4, the first sub-pixel SP1 and the second sub-pixel SP2 of the fifth pixel PXL5 may be defective. In this case, a black matrix may be disposed in the first sub-pixel SP1 and the second sub-pixel SP2 of the fifth pixel PXL5.

The first-type conversion may be performed to repair the first sub-pixel SP1 of the fifth pixel PXL5 in the second pixel PXL2 and the sixth pixel PXL6 that are adjacent to the first sub-pixel SP1 of the fifth pixel PXL5. For example, in the pixels PXL2 and PXL6, the first sub-pixel SP1 and the third sub-pixel SP3 may be converted. More particularly, in the pixels PXL2 and PXL6, blue light may be emitted from the first sub-pixel SP1, red light may be emitted from the third sub-pixel SP3, and a grayscale of the red light in each of the converted pixels PXL2 and PXL6 may be increased (e.g., from 50 to 53). To this end, in the pixels PXL2 and PXL6, a third color conversion layer that emits blue light may be disposed in the first sub-pixel SP1, and a first color conversion layer that emits red light may be disposed in the third sub-pixel SP3.

In addition, in order to repair the second sub-pixel SP2 of the fifth pixel PXL5, a grayscale of the fourth sub-pixel SP4 of the fifth pixel PXL5 may be increased (e.g., from 25 to 50).

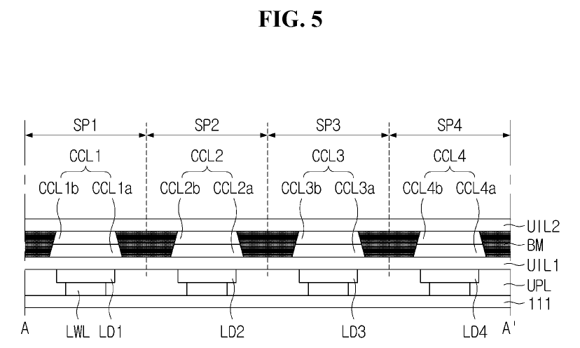

FIG. 5 is a cross-sectional view taken along line A-A’ of FIG. 4.

Referring to FIG. 5, the display panel may include first to fourth sub-pixels SP1, SP2, SP3, and SP4. The display panel may include a substrate 111, a lower layer LWL, an upper layer UPL, light-emitting elements LD1 to LD4, a first upper insulating layer UIL1, color conversion layers CCL1 to CCL4, a black matrix BM, and a second upper insulating layer UIL2. Red light may be emitted from the first sub-pixel SP1, green light may be emitted from the second sub-pixel SP2, blue light may be emitted from the third sub-pixel SP3, and green light may be emitted from the fourth sub-pixel SP4.

The substrate 111 may include a flexible plastic or a rigid material including glass (or quartz), but embodiments of the invention are not limited thereto.

Light-emitting elements LD1, LD2, LD3, and LD4 may be disposed to correspond to the sub-pixels SP1, SP2, SP3, and SP4 on the substrate 111, respectively. Each of the light-emitting elements LD1, LD2, LD3, and LD4 may include an inorganic light-emitting element and emit white light or blue light.

The lower layer LWL may be disposed below each of the light-emitting elements LD1, LD2, LD3, and LD4. The lower layer LWL may include at least one transistor, a capacitor, and at least one insulating layer.

The upper layer UPL may be disposed around the light-emitting elements LD1, LD2, LD3, and LD4. The upper layer UPL may include an electrode (or a line) that connects at least one transistor of the lower layer LWL to each of the light-emitting elements LD1, LD2, LD3, and LD4 and at least one insulating layer.

The light-emitting elements LD1, LD2, LD3, and LD4 may be disposed on the lower layers LWL of the sub-pixel SP1, SP2, SP3, and SP4, respectively.

A first upper insulating layer UIL1 may be disposed on the upper layer UPL and the light-emitting elements LD1 to LD4. The first upper insulating layer UIL1 may include an inorganic insulation material or an organic insulation material. The first upper insulating layer UIL1 may allow the upper color conversion layers CCL1 to CCL4 to be disposed flat.

The color conversion layers CCL1 to CCL4 may be disposed on the first upper insulating layer UIL1.

A first color conversion layer CCL1 may be disposed in the first sub-pixel SP1, a second color conversion layer CCL2 may be disposed in the second sub-pixel SP2, a third color conversion layer CCL3 may be disposed in the third sub-pixel SP3, and a fourth color conversion layer CCL4 may be disposed in the fourth sub-pixel SP4. The first color conversion layer CCL1 may include a material that emits red light and include a first color conversion material layer CCL1a and a first color filter CCL1b on the first color conversion material layer CCL1a. The first color conversion material layer CCL1a may include an organic phosphor, an inorganic phosphor, a quantum dot, or a color filter. The first color filter CCL1b may emit red light and block green light and blue light.

The second color conversion layer CCL2 may include a material that emits green light and include a second color conversion material layer CCL2a and a second color filter CCL2b on the second color conversion material layer CCL2a. The second color conversion material layer CCL2a may include an organic phosphor, an inorganic phosphor, a quantum dot, or a color filter. The second color filter CCL2b may emit green light and block blue light and red light.

The third color conversion layer CCL3 may include a material that emits blue light and include a third color conversion material layer CCL3a and a third color filter CCL3b on the third color conversion material layer CCL3a. The third color conversion material layer CCL3a may include an organic phosphor, an inorganic phosphor, a quantum dot, or a color filter. The third color filter CCL3b may emit blue light and block red light and green light.

The fourth color conversion layer CCL4 may include a material that emits green light and include a fourth color conversion material layer CCL4a and a fourth color filter CCL4b on the fourth color conversion material layer CCL4a. The fourth color conversion material layer CCL4a may include an organic phosphor, an inorganic phosphor, a quantum dot, or a color filter. The fourth color filter CCL4b may emit green light and block blue light and red light.

The black matrices BM may be disposed between adjacent color conversion layers CCL1, CCL2, CCL3, and CCL4. The black matrix BM may be disposed outside the color conversion layers CCL1 to CCL4 on the first upper insulating layer UIL1. Referring to FIG. 5, the black matrix BM may be disposed to fill gaps between the color conversion layers CCL1 to CCL4. Based on the cross-sectional view illustrated in FIG. 5, since the color conversion layers CCL1 to CCL4 are formed before the black matrix BM, the color conversion layers CCL1 to CCL4 may have a positive tapered shape, and the black matrix BM may have a negative tapered shape, but embodiments of the invention are not limited thereto.

The second upper insulating layer UIL2 may be disposed on the color conversion layers CCL1 to CCL4 and the black matrix BM. The second upper insulating layer UIL2 may protect the color conversion layers CCL1 to CCL4 from the outside. The second upper insulating layer UIL2 may include an inorganic insulation material or an organic insulation material.

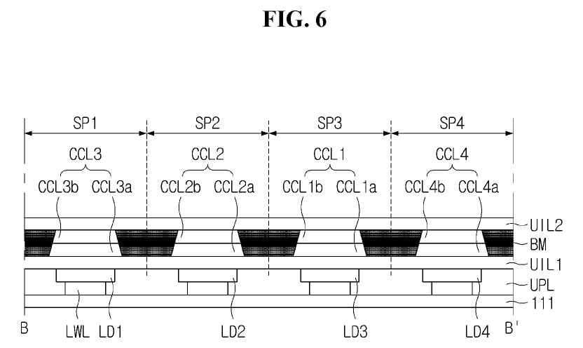

FIG. 6 is a cross-sectional view taken along line B-B’ of FIG. 4.

Referring to FIG. 6, blue light may be emitted from the first sub-pixel SP1, green light may be emitted from the second sub-pixel SP2, red light may be emitted from the third sub-pixel SP3, and green light may be emitted from the fourth sub-pixel SP4.

The first color conversion layer CCL1 may be disposed in the third sub-pixel SP3, the second color conversion layer CCL2 may be disposed in the second sub-pixel SP2, the third color conversion layer CCL3 may be disposed in the first sub-pixel SP1, and the fourth color conversion layer CCL4 may be disposed in the fourth sub-pixel SP4. The first color conversion layer CCL1 may include a material that emits red light, and the third color conversion layer CCL3 may include a material that emits blue light.

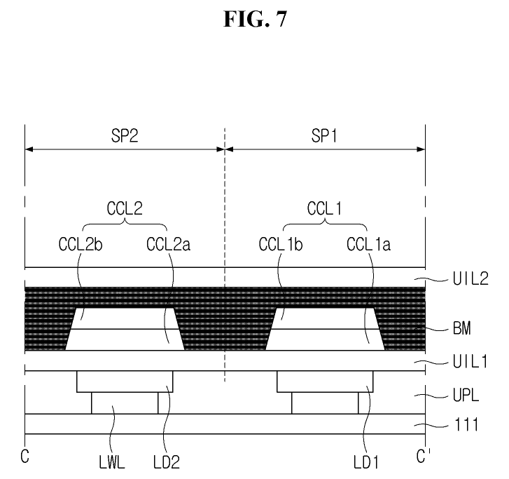

FIG. 7 is a cross-sectional view taken along line C-C’ of FIG. 4.

Referring to FIG. 7, light may not be emitted from defective sub-pixels, more particularly, the first sub-pixel SP1 and the second sub-pixel SP2. To this end, the black matrices BM may be disposed to at least partially overlap the color conversion layers CCL1 and CCL2 and light-emitting elements LD1 and LD2.

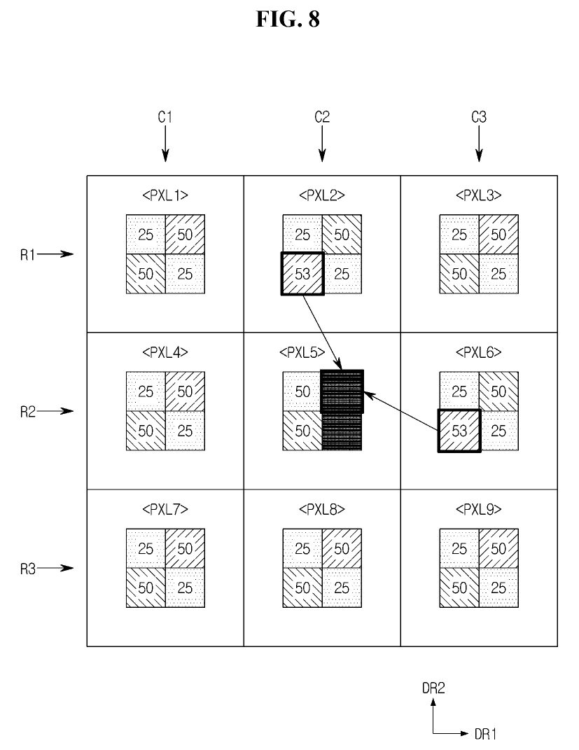

FIG. 8 is a diagram illustrating a repair to which the first-type conversion in FIG. 3 is applied.

According to an embodiment, the first sub-pixel SP1 and the fourth sub-pixel SP4 of the fifth pixel PXL5 may be defective. In this case, the black matrices may be disposed in the first sub-pixel SP1 and the fourth sub-pixel SP4 of the fifth pixel PXL5.

The first-type conversion may be performed to repair the first sub-pixel SP1 of the fifth pixel PXL5 in the second pixel PXL2 and the sixth pixel PXL6 that are adjacent to the first sub-pixel SP1 of the fifth pixel PXL5. For example, in the pixels PXL2 and PXL6, the first sub-pixel SP1 and the third sub-pixel SP3 may be converted. Since this has been described above with reference to FIG. 4, the detailed description thereof will be omitted.

In addition, in order to repair the fourth sub-pixel SP4 of the fifth pixel PXL5, a grayscale of the second sub-pixel SP2 of the fifth pixel PXL5 may be increased (e.g., from 25 to 50).

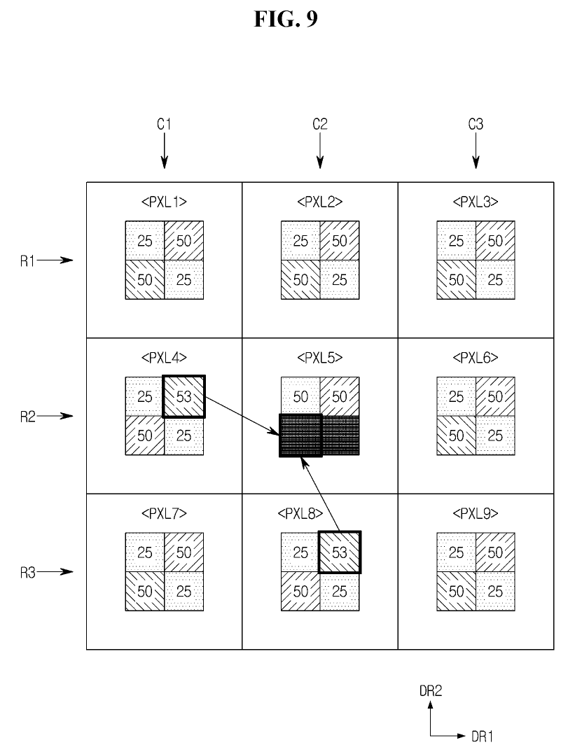

FIG. 9 is a diagram illustrating a repair to which the first-type conversion in FIG. 3 is applied.

According to an embodiment, the third sub-pixel SP3 and the fourth sub-pixel SP4 of the fifth pixel PXL5 may be defective. In this case, the black matrices may be disposed in the third sub-pixel SP3 and the fourth sub-pixel SP4 of the fifth pixel PXL5.

The first-type conversion may be performed to repair the third sub-pixel SP3 of the fifth pixel PXL5 in the fourth pixel PXL4 and the eighth pixel PXL8 that are adjacent to the third sub-pixel SP3 of the fifth pixel PXL5. For example, in the pixels PXL4 and PXL8, the first sub-pixel SP1 and the third sub-pixel SP3 may be converted. More particularly, in the pixels PXL4 and PXL8, blue light may be emitted from the first sub-pixel SP1, red light may be emitted from the third sub-pixel SP3, and a grayscale of the blue light in each of the converted pixels PXL4 and PXL8 may be increased (e.g., from 50 to 53). To this end, in the pixels PXL4 and PXL8, the third color conversion layer that emits blue light may be disposed in the first sub-pixel SP1, and the first color conversion layer that emits red light may be disposed in the third sub-pixel SP3.

In addition, in order to repair the fourth sub-pixel SP4 of the fifth pixel PXL5, a grayscale of the second sub-pixel SP2 of the fifth pixel PXL5 may be increased (e.g., from 25 to 50).

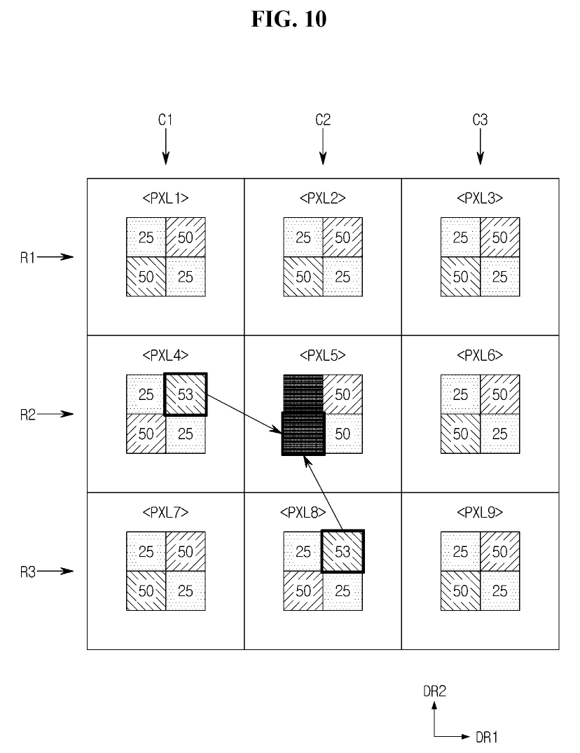

FIG. 10 is a diagram illustrating a repair to which the first-type conversion in FIG. 3 is applied.

According to an embodiment, the second sub-pixel SP2 and the third sub-pixel SP3 of the fifth pixel PXL5 may be defective. In this case, the black matrices may be disposed in the second sub-pixel SP2 and the third sub-pixel SP3 of the fifth pixel PXL5.

The first-type conversion may be performed to repair the third sub-pixel SP3 of the fifth pixel PXL5 in the fourth pixel PXL4 and the eighth pixel PXL8 that are adjacent to the third sub-pixel SP3 of the fifth pixel PXL5. For example, in the pixels PXL4 and PXL8, the first sub-pixel SP1 and the third sub-pixel SP3 may be converted. More particularly, in the pixels PXL4 and PXL8, blue light may be emitted from the first sub-pixel SP1, red light may be emitted from the third sub-pixel SP3, and a grayscale of the blue light in each of the converted pixels PXL4 and PXL8 may be increased (e.g., from 50 to 53). To this end, in the pixels PXL4 and PXL8, the third color conversion layer that emits blue light may be disposed in the first sub-pixel SP1, and the first color conversion layer that emits red light may be disposed in the third sub-pixel SP3.

In addition, in order to repair the second sub-pixel SP2 of the fifth pixel PXL5, a grayscale of the fourth sub-pixel SP4 of the fifth pixel PXL5 may be increased (e.g., from 25 to 50).

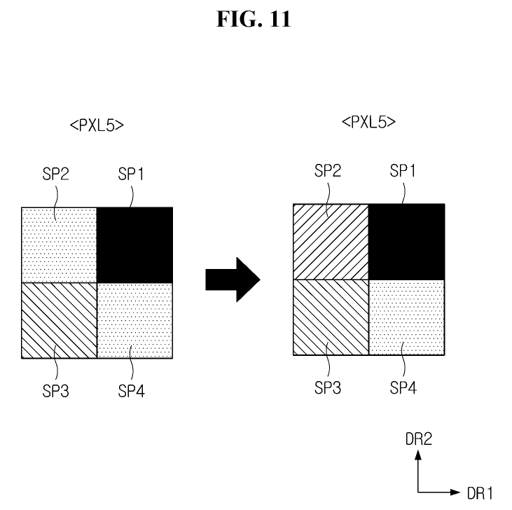

FIG. 11 is a diagram illustrating a second-type conversion between sub-pixels within a pixel according to an embodiment.

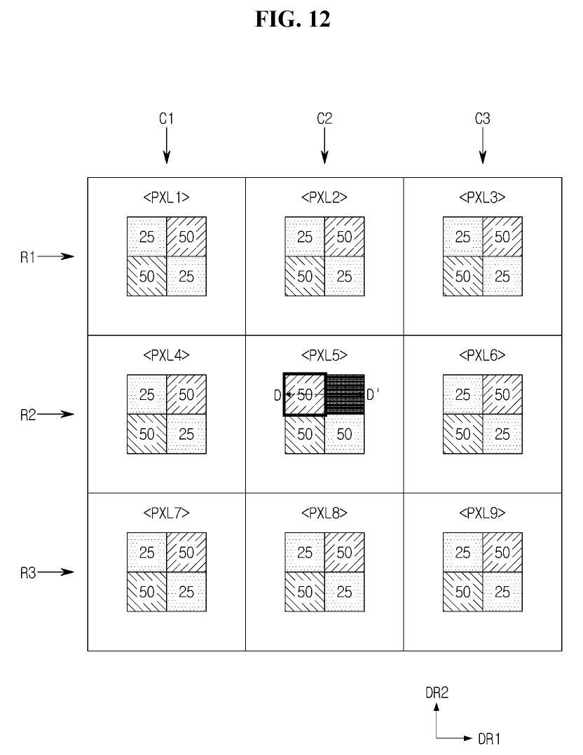

FIG. 11 illustrates sub-pixels of the fifth pixel PXL5 in FIG. 12. The left drawing of FIG. 11 illustrates the fifth pixel PXL5 before the second-type conversion is applied, and the right drawing of FIG. 11 illustrates the fifth pixel PXL5 to which the second-type conversion is applied.

As illustrated in the left drawing of FIG. 11, the first sub-pixel SP1 may not emit light, and the second sub-pixel SP2 may emit green light.

As illustrated in the right drawing of FIG. 11 to which the second-type conversion is applied, the color of light emitted from the second sub-pixel SP2 may be changed (green to red).

FIG. 12 is a diagram illustrating a repair to which the second-type conversion in FIG. 11 is applied.

According to an embodiment, the first sub-pixel SP1 of the fifth pixel PXL5 may be defective. In this case, a black matrix may be disposed in the first sub-pixel SP1 of the fifth pixel PXL5.

The second-type conversion may be performed to repair the first sub-pixel SP1 of the fifth pixel PXL5. For example, in the fifth pixel PXL5, the first sub-pixel SP1 and the second sub-pixel SP2 may be converted. More particularly, in the fifth pixel PXL5, red light may be emitted from the second sub-pixel SP2. To this end, in the fifth pixel PXL5, the first color conversion layer that emits red light may be disposed in the second sub-pixel SP2. In addition, the black matrix BM may be disposed in the first sub-pixel SP1, and a grayscale of the green light emitted from the fourth sub-pixel SP4 may be increased (from 25 to 50).

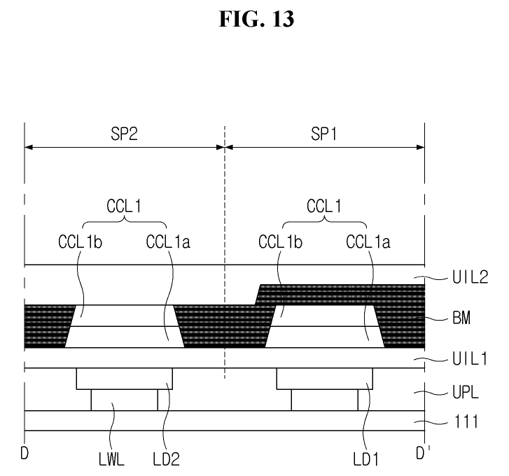

FIG. 13 is a cross-sectional view taken along line D-D’ of FIG. 12.

Referring to FIG. 13, light may not be emitted from the first sub-pixel SP1, but red light may be emitted from the second sub-pixel SP2.

The first color conversion layer CCL1 may be disposed in the second sub-pixel SP2. The first color conversion layer CCL1 may include a material that emits red light.

The black matrix BM may be disposed to at least partially overlap the first color conversion layer CCL1 and the first light-emitting element LD1 of the first sub-pixel SP1.

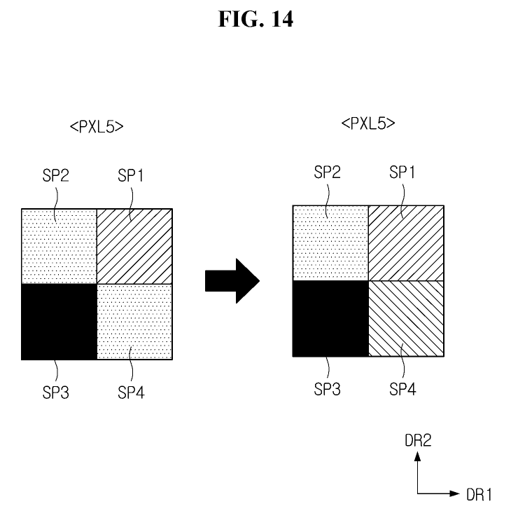

FIG. 14 is a diagram illustrating a third-type conversion between sub-pixels within a pixel according to an embodiment.

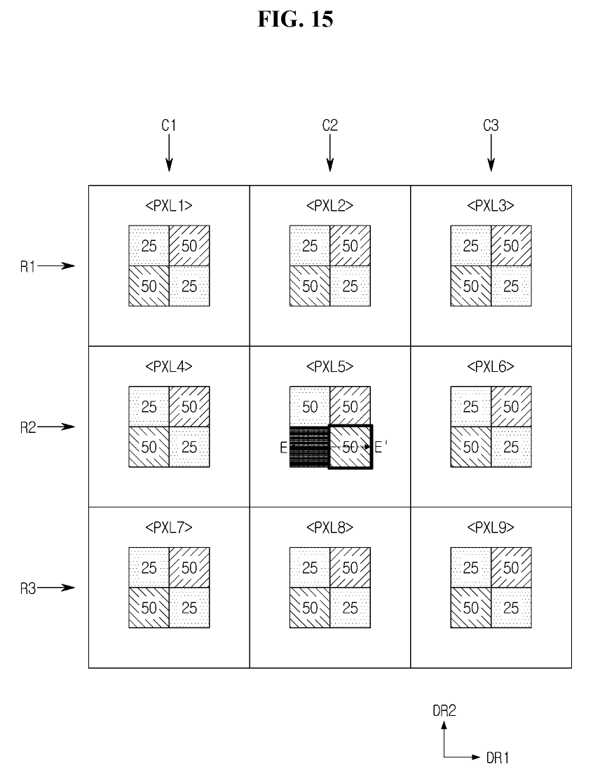

FIG. 14 illustrates the sub-pixels of the fifth pixel PXL5 in FIG. 15. The left drawing of FIG. 14 illustrates the fifth pixel PXL5 before the third-type conversion is applied, and the right drawing of FIG. 14 illustrates the fifth pixel PXL5 to which the third-type conversion is applied.

As illustrated in the left drawing of FIG. 14, the third sub-pixel SP3 may not emit light, and the fourth sub-pixel SP4 may emit green light.

As illustrated in the right drawing of FIG. 14 to which the third-type conversion is applied, the color of light emitted from the fourth sub-pixel SP4 may be changed (green to blue).

FIG. 15 is a diagram illustrating a repair to which the third-type conversion in FIG. 14 is applied. According to an embodiment, the third sub-pixel SP3 of the fifth pixel PXL5 may be defective. In this case, a black matrix may be disposed in the third sub-pixel SP3 of the fifth pixel PXL5.

The third-type conversion may be performed to repair the third sub-pixel SP3 of the fifth pixel PXL5. For example, in the fifth pixel PXL5, the third sub-pixel SP3 and the fourth sub-pixel SP4 may be converted. More particularly, in the fifth pixel PXL5, light may not be emitted from the third sub-pixel SP3, and blue light may be emitted from the fourth sub-pixel SP4. To this end, in the fifth pixel PXL5, the third color conversion layer that emits blue light may be disposed in the fourth sub-pixel SP4. In addition, the black matrix BM may be disposed in the third sub-pixel SP3, and a grayscale of the green light emitted from the second sub-pixel SP2 may be increased (from 25 to 50).

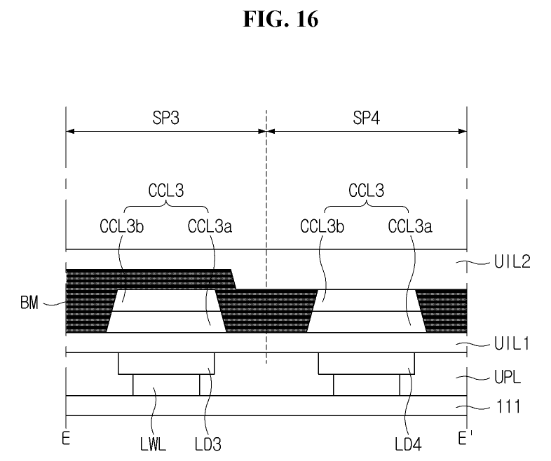

FIG. 16 is a cross-sectional view taken along line E-E’ of FIG. 15.

Referring to FIG. 16, light may not be emitted from the third sub-pixel SP3, but blue light may be emitted from the fourth sub-pixel SP4.

The third color conversion layer CCL3 may be disposed in the fourth sub-pixel SP4. The third color conversion layer CCL3 may include a material that emits blue light.

The black matrix BM may be disposed to at least partially overlap the third color conversion layer CCL3 and the third light-emitting element LD3 of the third sub-pixel SP3.

According to an embodiment of the display device, in order to repair the defective sub-pixel, as described with reference to FIG. 3, the first sub-pixel SP1 and the third sub-pixel SP3 may be converted (first-type conversion), as described with reference to FIG. 11, the second sub-pixel SP2 and the first sub-pixel SP1 may be converted (second-type conversion), and as described with reference to FIG. 14, the third sub-pixel SP3 and the fourth sub-pixel SP4 may be converted (third-type conversion).

Meanwhile, required currents for driving the sub-pixels SP1 to SP4 (for driving the transistors and controlling the light-emitting elements LD1 to LD4 to emit light) may be different for each of the first sub-pixel SP1, the second sub-pixel SP2, the third sub-pixel SP3, and the fourth sub-pixel SP4.

For example, the required current of the first sub-pixel SP1 that emits red light may be the highest, followed by the required currents of the second and fourth sub-pixels SP2 and SP4 that emit green light, and finally, the required current of the third sub-pixel SP3 that emits blue light may be the lowest. For example, the required currents of the second sub-pixel SP2 and the fourth sub-pixel SP4 may be about 0.66 times the required current of the first sub-pixel SP1, and the required current of the third sub-pixel SP3 may be about 0.53 times the required current of the first sub-pixel SP1. Accordingly, it is necessary to optimize the sub-pixel design for each of the sub-pixels SP1, SP2, SP3, and SP4 that have different required currents.

A key factor in designing sub-pixels to meet the current requirements may be a width/length (W/L) of the semiconductor layer of the driving transistor DT (see FIG. 2). Specifically, the driving current flowing from the source electrode to the drain electrode of the driving transistor DT may be proportional to the width/length (W/L) of the semiconductor layer of the driving transistor DT. When the driving current reaches a target current level, the required current may be considered to be satisfied. Accordingly, even when the same data signal VDATA and driving voltage VDD are applied to the sub-pixels, the required currents may be different for each of the sub-pixels SP1 to SP4, and thus it is necessary to differently design the width/length (W/L) of the semiconductor layer of the driving transistor DT for each of the sub-pixels SP1 to SP4.

However, according to embodiments of the invention, each of the sub-pixels SP1 to SP4 may be converted. More particularly, the first sub-pixel SP1 and the second sub-pixel SP2 and the third sub-pixel SP3, which will be converted, need to have the same width/length of the semiconductor layer of the driving transistor DT as the first sub-pixel SP1 depending on the current requirement of the first sub-pixel SP1, which has the highest current requirement. In addition, since the fourth sub-pixel SP4 and the third sub-pixel SP3 are converted, the width/length of the semiconductor layer of the driving transistor DT may be designed to correspond to the fourth sub-pixel SP4, which has a higher current requirement than the third sub-pixel SP3.

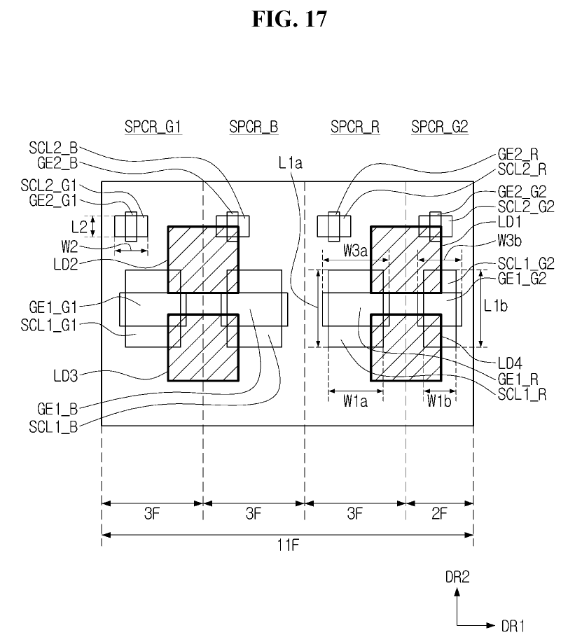

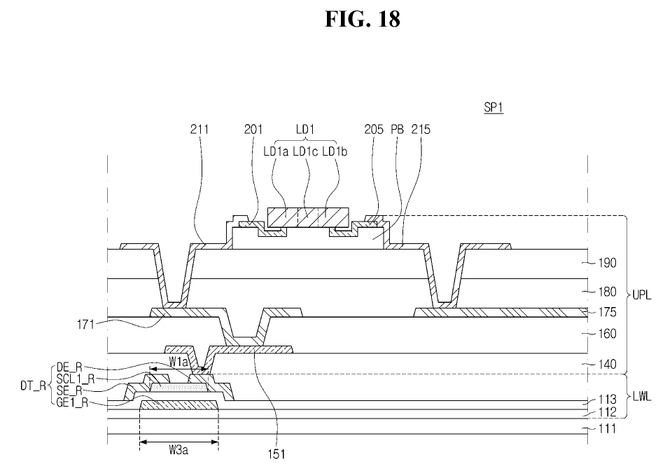

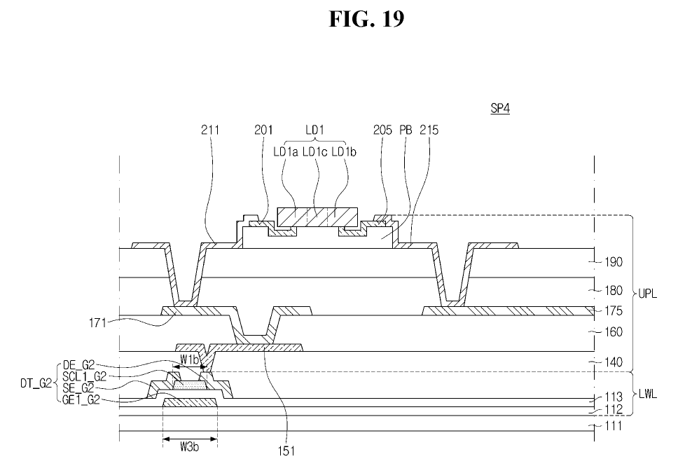

FIG. 17 is a layout diagram of a pixel according to an embodiment of the invention. FIG. 18 is a cross-sectional view of a first sub-pixel in FIG. 17. FIG. 19 is a cross-sectional view of a fourth sub-pixel in FIG. 17.

Referring to FIG. 17, areas in which the transistors of the sub-pixels SP1 to SP4 are disposed are illustrated. From the other side in the first direction DR1, a second circuit area SPCR_G1 of the second sub-pixel SP2, a third circuit area SPCR_B of the third sub-pixel SP3, a first circuit area SPCR_R of the first sub-pixel SP1, and a fourth circuit area SPCR_G2 of the fourth sub-pixel SP4 may be arranged. However, embodiments of the invention are not limited to the arrangement of the circuit areas and the arrangement of the transistors disposed in the circuit areas as illustrated in FIG. 17, and may vary depending on the design.

A 1a driving transistor and a 1a switching transistor may be disposed in the first circuit area SPCR_R, a 1b driving transistor and a 1b switching transistor may be disposed in the second circuit area SPCR_G1, a 1c driving transistor and a 1c switching transistor may be disposed in the third circuit area SPCR_B, and a 1d driving transistor and a 1d switching transistor may be disposed in the fourth circuit area SPCR_G2.

The first light-emitting element LD1 may be disposed at an upper right, the second light-emitting element LD2 may be disposed at an upper left, the third light-emitting element LD3 may be disposed at a lower left, and the fourth light-emitting element LD4 may be disposed at a lower right. For example, the first light-emitting element LD1 may be disposed between the first circuit area SPCR_R and the fourth circuit area SPCR_G2, the second light-emitting element LD2 may be disposed between the second circuit area SPCR_G1 and the third circuit area SPCR_B, the third light-emitting element LD3 may be disposed between the second circuit area SPCR_G1 and the third circuit area SPCR_B, and the fourth light-emitting element LD4 may be disposed between the first circuit area SPCR_R and the fourth circuit area SPCR_G2. Areas of the light-emitting elements LD1 to LD4 may be the same, but embodiments of the invention are not limited thereto.

As described above with reference to FIGS. 3, 11, and 14, the first sub-pixel SP1 and the second sub-pixel SP2 and the third sub-pixel SP3, which will be converted, need to have the same width/length of the semiconductor layer of the driving transistor as the first sub-pixel SP1 according to the required current of the first sub-pixel SP1. In addition, since the fourth sub-pixel SP4 and the third sub-pixel SP3 are converted, the width/length of the semiconductor layer of the driving transistor DT may be designed to correspond to the fourth sub-pixel SP4, which has a higher current requirement than the third sub-pixel SP3. More particularly, a width/length (W1a/L1a) of a 1a semiconductor layer SCL1_R of the driving transistor of the first sub-pixel SP1 may be the same as a width/length (W1a/L1a) of a 1b semiconductor layer SCL1_G1 of the driving transistor of the second sub-pixel SP2 and a 1c semiconductor layer SCL1_B of the driving transistor of the third sub-pixel SP3, and the width/length (W1a/L1a) of the 1a semiconductor layer SCL1_R of the driving transistor of the first sub-pixel SP1 may be greater than a width/length (W1b/L1b) of a 1d semiconductor layer SCL1_G2 of the driving transistor of the fourth sub-pixel SP4. For example, the width/length (W1a/L1a) of the first semiconductor layer SCL1_R may be about 1.5 times greater than the width/length (W1b/L1b) of the 1d semiconductor layer SCL1_G2 according to the magnitude of the required current, but embodiments of the invention are not limited thereto. For example, the length L1a of the first semiconductor layer SCL1_R may be the same as the length L1b of the first semiconductor layer SCL1_G2, and the width W1a of the first semiconductor layer SCL1_R may be about 1.5 times the width W1b of the first semiconductor layer SCL1_G2, but embodiments of the invention are not limited thereto.

Meanwhile, a width of a first gate electrode of each of the sub-pixels SP1 to SP4 may also be proportional to the width of each of the semiconductor layers SCL1_R, SCL1_G1, SCL1_B, and SCL1_G2 of the driving transistor. Accordingly, a width W3a of a 1a gate electrode GE1_R may be the same as a width W3a of a 1b gate electrode GE1_G1 and a width W3a of a 1c gate electrode GE1_B and may be greater than a width W3b of a 1d gate electrode GE1_G2.

On the other hand, widths/lengths of semiconductor layers of the switching transistors of the sub-pixel SP1 to SP4 may be the same. More particularly, widths W2 and lengths L2 of second semiconductor layers SCL2_R1, SCL2_G1, SCL2_B, and SCL2_G2 of the switching transistor of the sub-pixels SP1 to SP4 may be the same. Accordingly, the width of the second gate electrode of the switching transistor of each of the sub-pixels SP1 to SP4 may be the same as that of each of the semiconductor layers SCL2_R, SCL2_G1, SCL2_B, and SCL2_G2.

As described above, since the width/length (W1a/L1a) of the 1a semiconductor layer SCL1_R of the driving transistor of the first sub-pixel SP1 may be greater than the width/length (W1b/L1b) of the 1d semiconductor layer SCL1_G2 of the driving transistor of the fourth sub-pixel SP4, and the width/length (W1a/L1a) of the 1a semiconductor layer SCL1_R of the driving transistor of the first sub-pixel SP1 may be the same as the width/length (W1a/L1a) of the 1b semiconductor layer SCL1_G1 of the driving transistor of the second sub-pixel SP2, and the width/length (W1a/L1a) of the 1c semiconductor layer SCL1_B of the driving transistor of the third sub-pixel SP3, as illustrated in FIG. 17, widths of the circuit areas SPCR_R, SPCR_G1, SPCR_B, and SPCR_G2 may also be different.

For example, the first circuit area SPCR_R may have a third width 3F, the second circuit area SPCR_G1 may have the third width 3F, the third circuit area SPCR_B may have the third width 3F, and the fourth circuit area SPCR_G2 may have a second width 2F.

According to embodiments of the invention, the circuit areas SPCR_R, SPCR_G1, SPCR_B, and SPCR_G2 of the sub-pixels SP1 to SP4 are designed in consideration of the required currents of the sub-pixels SP1 to SP4 and the conversion method for repair, thereby reducing the area (or the width) of the fourth circuit area SPCR_G2. Accordingly, there is an advantage in that additional design space can be secured in the circuit area.

Hereinafter, a specific cross-sectional structure of the first sub-pixel SP1 and the fourth sub-pixel SP4 will be described.

Referring to FIGS. 18 and 19, the lower layer LWL may be disposed on the substrate 111, the upper layer UPL may be disposed on the lower layer LWL, and the light-emitting elements LD1 and LD4 may be disposed on the upper layer UPL.

The lower layer LWL may include a buffer layer 112, one or more transistors DT_R and DT_G2, a gate insulating layer 113, and a first protective layer 140, and the upper layer UPL may include a lower connection electrode 151, a second protective layer 160, upper connection electrodes 171 and 175, a planarization layer 180, an adhesive layer 190, a circuit board PB, upper contact electrodes 211 and 215, a first electrode 201, and a second electrode 205.

The buffer layer 112 may be disposed on the substrate 111. The buffer layer 112 can minimize or delay the diffusion of moisture or oxygen penetrating the substrate 111. The buffer layer 112 may be formed by alternately stacking silicon nitride (SiNₓ) and silicon oxide (SiOₓ) at least once, but embodiments of the invention are not limited thereto.

A transistor may be disposed on the buffer layer 112. The transistor may be a driving transistor. For example, a 1a transistor DT_R may be disposed in the first sub-pixel SP1, and a 1d transistor DT_G2 may be disposed in the fourth sub-pixel SP4. The 1a transistor DT_R may include the 1a semiconductor layer SCL1_R, a 1a gate electrode GE1_R, a 1a source electrode SE_R, and a 1a drain electrode DE_R, and the 1d transistor DT_G2 may include the 1d semiconductor layer SCL1_G2, the 1d gate electrode GE1_G2, a 1d source electrode SE_G2, and a 1d drain electrode DE_G2.

The gate electrodes GE1_R and GE1_G2 may be disposed on the buffer layer 112. The gate electrodes GE1_R and GE1_G2 may be made of a semiconductor, such as silicon (Si) or the like, or a conductive metal, for example, any one of molybdenum (Mo), aluminum (Al), chromium (Cr), gold (Au), titanium (Ti), nickel (Ni), neodymium (Nd), and copper (Cu), an alloy of two or more thereof, or multiple layers thereof.

The gate insulating layer 113 may be disposed on the gate electrodes GE1_R and GE1_G2. The gate insulating layer 113 may be formed of a single layer or multiple layers of inorganic materials, such as silicon oxide (SiOₓ), silicon nitride (SiNₓ), without being limited thereto. The gate insulating layer 113 may insulate the gate electrodes GE1_R and GE1_G2 from the semiconductor layers SCL1_R and SCL1_G2.

The semiconductor layers SCL1_R and SCL1_G2 may be disposed on the gate insulating layer 113. The semiconductor layers SCL1_R and SCL1_G2 are provided in a preset pattern shape on the gate insulating layer 113 to at least partially overlap the gate electrodes GE1_R and GE1_G2, respectively. The semiconductor layers SCL1_R and SCL1_G2 may be formed of a semiconductor material including any one of amorphous silicon, polycrystalline silicon, oxide, and an organic material, but embodiments of the invention are not limited thereto.

The source electrodes SE_R and SE_G2 and the drain electrodes DE_R and DE_G2 may be disposed on the semiconductor layers SCL1_R and SCL1_G2, respectively. The source electrodes SE_R and SE_G2 may be disposed to at least partially overlap the other sides of the semiconductor layers SCL1_R and SCL1_G2 in the first direction DR1, respectively, and the drain electrodes DE_R and DE_G2 may be disposed to at least partially overlap one sides of the semiconductor layers SCL1_R and SCL1_G2 in the first direction DR1, respectively.

In the present specification, the gate electrodes GE1_R and GE1_G2 are described as being disposed below the semiconductor layers SCL1_R and SCL1_G2, respectively, but embodiments of the invention are not limited thereto, and may be disposed on the semiconductor layers SCL1_R and SCL1_G2, respectively, and the source electrodes SE_R and SE_G2 and the drain electrodes DE_R and DE_G2 may be electrically connected to the semiconductor layers SCL1_R and SCL1_G2 through the gate insulating layer 113, respectively. The source electrodes SE_R and SE_G2 and the drain electrodes DE_R and DE_G2 may be formed of a semiconductor such as silicon (Si), a conductive metal, for example, any one of molybdenum (Mo), aluminum (Al), chromium (Cr), gold (Au), titanium (Ti), nickel (Ni), neodymium (Nd), and copper (Cu), an alloy of two or more thereof, or a multilayer thereof. However, embodiments of the invention are not limited thereto.

The first protective layer 140 may be disposed on the source electrodes SE_R and SE_G2 and the drain electrodes DE_R and DE_G2. The first protective layer 140 may protect the underlying transistors DT_R and DT_G2 and provide a flat surface. According to an embodiment, the first protective layer 140 may be formed of an organic material such as benzocyclobutene or photo acryl, but embodiments of the invention are not limited thereto.

The lower connection electrode 151 may be disposed on the first protective layer 140. The lower connection electrode 151 may be formed of any one of molybdenum (Mo), aluminum (Al), chromium (Cr), gold (Au), titanium (Ti), nickel (Ni), neodymium (Nd), and copper (Cu), an alloy of two or more thereof, or multiple layers thereof. In each of the first and fourth sub-pixels SP1 and SP4, the lower connection electrode 151 may be electrically connected to the drain electrodes DE_R and DE_G2 through the first protective layer 140.

The second protective layer 160 may be disposed on the lower connection electrode 151. A material of the second protective layer 160 may be one of the above examples of the first protective layer 140, but embodiments of the invention are not limited thereto.

The first and second upper connection electrodes 171 and 175 may be disposed on the second protective layer 160. The first and second upper connection electrodes 171 and 175 may include the same material and may be disposed on the same layer. The first and second upper connection electrodes 171 and 175 may be formed of at least one of molybdenum (Mo), aluminum (Al), chromium (Cr), gold (Au), titanium (Ti), nickel (Ni), neodymium (Nd), and copper (Cu), an alloy of two or more thereof, or multiple layers thereof. The first upper connection electrode 171 may be electrically connected to the lower connection electrode 151 through the second protective layer 160. A common voltage (or a cathode voltage) may be applied to the second upper connection electrode 175. The second upper connection electrode 175 may be a low-potential voltage line, but embodiments of the invention are not limited thereto.

The planarization layer 180 may be disposed on the first and second upper connection electrodes 171 and 175. The planarization layer 180 can minimize movements of the element contact electrodes 220 and 230 and the light-emitting element 210 disposed on the planarization layer 180. The planarization layer 180 may include an organic insulation material, but embodiments of the invention are not limited thereto.

The adhesive layer 190 may be disposed on the planarization layer 180. The circuit board PB to be described below may be adhered to a surface of the adhesive layer 190 through the adhesive layer 190.

The circuit board PB may be disposed on the adhesive layer 190. The first electrode 201 and the second electrode 205 may be disposed inside the circuit board PB. The first electrode 201 may serve as an anode, and the second electrode 205 may serve as a cathode, but embodiments of the invention are not limited thereto, and the opposite configuration may also be possible. The light-emitting elements LD1 and LD4 may be disposed on the circuit board PB. The first light-emitting element LD1 may be disposed in the first sub-pixel SP1, and the fourth light-emitting element LD4 may be disposed in the fourth sub-pixel SP4. The light-emitting elements LD1 and LD4 may include first areas LD1a and LD4a, second areas LD1b and LD4b, and active layers LD1c and LD4c interposed therebetween, respectively.

The first areas LD1a and LD4a may be p-type electrodes (or p-type materials) and connected to the first electrode 201, and the second areas LD1b and LD4b may be n-type electrodes (or n-type materials) and connected to the second electrode 205. In the active layers LD1c and LD4c, electrons and holes generated by current flowing between the first areas LD1a and LD4a connected to the first electrode 201 and the second areas LD1b and LD4b connected to the second electrode 205 may be recombined, thereby enabling the active layers LD1c and LD4c to emit light. The first upper contact electrode 211 may be connected to the first areas LD1a and LD4a via the first electrode 201, and the second upper contact electrode 215 may be connected to the second areas LD1b and LD4b via the second electrode 205. The first upper contact electrode 211 and the second upper contact electrode 215 may be electrically connected to the upper connection electrodes 171 and 175 through the adhesive layer 190 and the planarization layer 180, respectively.

In the present specification, the second upper connection electrode 175 is described as being disposed on the same layer as the first upper connection electrode 171, but embodiments of the invention are not limited thereto, and the second upper connection electrode 175 may also be disposed on the same layer as the lower connection electrode 151. In this case, the second upper connection electrode 175 may not be directly connected to the second upper contact electrode 215, and a separate connection electrode may be added to electrically connect the second upper connection electrode 175 to the second upper contact electrode 215. In some embodiments, the second upper connection electrode 175 may be disposed on the same layer as the first upper connection electrode 171, but a separate connection electrode may be added to electrically connect the second upper connection electrode 175 to the second upper contact electrode 215. The connection electrode may be disposed between the planarization layer 180 and the adhesive layer 190.

In the present embodiment, as described above, the width/length (W1a/L1a) of the 1a semiconductor layer SCL1_R of the driving transistor of the first sub-pixel SP1 may be greater than the width/length (W1b/L1b) of the 1d semiconductor layer SCL1_G2 of the driving transistor of the fourth sub-pixel SP4. When the lengths L1a and L1b are the same, the width W1a of the first semiconductor layer SCL1_R may be greater than the width W1b of the 1d semiconductor layer SCL1_G2.

Furthermore, the width W3a of the first gate electrode GE1_R may be greater than the width W3b of the 1d gate electrode GE1_G2.

According to embodiments of the invention, the circuit areas SPCR_R, SPCR_G1, SPCR_B, and SPCR_G2 of the sub-pixels SP1 to SP4 are designed in consideration of the required currents of the sub-pixels SP1 to SP4 and the conversion method for repair, thereby reducing the area (or the width) of the fourth circuit area SPCR_G2. Accordingly, there is an advantage in that additional design space can be secured in the circuit area.

A display device according to embodiments of the invention may be described as follows.

According to embodiments of the invention, a display device includes a substrate on which a first sub-pixel and a fourth sub-pixel are defined, a 1a transistor and a 1d transistor on the substrate, and a first light-emitting element connected to the 1a transistor and disposed on the first sub-pixel, and a fourth light-emitting element connected to the 1d transistor and disposed on the fourth sub-pixel, in which each of the first light-emitting element and the fourth light-emitting element includes an inorganic light-emitting element, red light or blue light is emitted from the first sub-pixel, green light or blue light is emitted from the fourth sub-pixel, each of the 1a transistor and the 1d transistor is a driving transistor, and a width of a 1a semiconductor layer of the 1a transistor is greater than a width of a 1d semiconductor layer of the 1d transistor.

In the display device according to embodiments of the invention, a length of the 1a semiconductor layer may be the same as a length of the 1d semiconductor layer.

In the display device according to embodiments of the invention, the 1a transistor may further include a 1a gate electrode on the 1a semiconductor layer, the 1d transistor may further include a 1d gate electrode on the 1d semiconductor layer, and a width of the 1a gate electrode may be greater than a width of the 1d gate electrode.

The display device according to embodiments of the invention may further include a 2a transistor connected to the 1a gate electrode, and a 2d transistor connected to the 1d gate electrode, in which a width of a 2a semiconductor layer of the 2a transistor may be the same as a width of a 2d semiconductor layer of the 2d transistor.

In the display device according to embodiments of the invention, a length of the 2a semiconductor layer may be the same as a length of the 2d semiconductor layer.

In the display device according to embodiments of the invention, the 2a transistor and the 2d transistor may be switching transistors.

The display device according to embodiments of the invention may further include a second sub-pixel defined on the substrate, a 1b transistor on the substrate, and a second light-emitting element connected to the 1b transistor and disposed on the second sub-pixel, in which the second light-emitting element may include the inorganic light-emitting element, the green light or the red light may be emitted from the second sub-pixel, the 1b transistor may be the driving transistor, and a width of a 1b semiconductor layer of the 1b transistor may be greater than a width of the 1d semiconductor layer.

In the display device according to embodiments of the invention, the width of the 1b semiconductor layer may be the same as the width of the 1a semiconductor layer.

In the display device according to embodiments of the invention, a length of the 1b semiconductor layer may be the same as the length of the 1a semiconductor layer.

In the display device according to embodiments of the invention, the second sub-pixel may be positioned at a left side of the first sub-pixel in a plan view, and the fourth sub-pixel may be positioned below the first sub-pixel in a plan view.

The display device according to embodiments of the invention may further include a third sub-pixel defined on the substrate, a 1c transistor on the substrate, and a third light-emitting element connected to the 1c transistor and disposed on the third sub-pixel, in which the third light-emitting element may include an inorganic light-emitting element, the blue light and the red light may be emitted from the third sub-pixel, the 1c transistor may be the driving transistor, and a width of the 1c semiconductor layer of the 1c transistor may be greater than a width of the 1d semiconductor layer.

In the display device according to embodiments of the invention, the width of the 1c semiconductor layer may be the same as the width of the 1a semiconductor layer.

In the display device according to embodiments of the invention, a length of the 1c semiconductor layer may be the same as the length of the 1a semiconductor layer.

The display device according to embodiments of the invention may further include a first color conversion layer on the first light-emitting element, a second color conversion layer on the second light-emitting element, a third color conversion layer on the third light-emitting element, and a fourth color conversion layer on the fourth light-emitting element, in which the first color conversion layer may emit the red light or the blue light, the second color conversion layer may emit the green light or the red light, the third color conversion layer may emit the blue light or the red light, and the fourth color conversion layer may emit the green light or the blue light.

In the display device according to embodiments of the invention, a required current for driving the first sub-pixel may be higher than a required current for driving the second sub-pixel and a required current for driving the fourth sub-pixel.

In the display device according to embodiments of the invention, the required current for driving the second sub-pixel may be higher than a required current for driving the third sub-pixel.

According to embodiments of the invention, a display device includes a first pixel which includes a first sub-pixel, a second sub-pixel, a third sub-pixel, and a fourth sub-pixel and in which a black matrix is disposed on at least one of the sub-pixels, and a second pixel which is disposed adjacent to the first pixel and includes the first sub-pixel, the second sub-pixel, the third sub-pixel, and the fourth sub-pixel, in which in the first pixel, a first color conversion layer is disposed on the first sub-pixel, a second color conversion layer is disposed on the second sub-pixel, a third color conversion layer is disposed on the third sub-pixel, and a fourth color conversion layer is disposed on the fourth sub-pixel, and in the second pixel, a color conversion layer disposed on at least one of the first sub-pixel, the second sub-pixel, the third sub-pixel, and the fourth sub-pixel is different from a color conversion layer disposed on a corresponding sub-pixel in the first pixel.

In the display device according to embodiments of the invention, in the first pixel, the black matrix may be disposed in the first sub-pixel and the second sub-pixel, and in the second pixel, the third color conversion layer may be disposed in the first sub-pixel and the first color conversion layer may be disposed in the third sub-pixel.

In the display device according to embodiments of the invention, in the first pixel, the black matrix may be disposed in the first sub-pixel and the third sub-pixel, and in the second pixel, the third color conversion layer may be disposed in the first sub-pixel and the first color conversion layer may be disposed in the third sub-pixel.

In the display device according to embodiments of the invention, in the first pixel, the black matrix may be disposed in the third sub-pixel and the fourth sub-pixel, and in the second pixel, the third color conversion layer may be disposed in the first sub-pixel and the first color conversion layer may be disposed in the third sub-pixel.

In the display device according to embodiments of the invention, in the first pixel, the black matrix may be disposed in the second sub-pixel and the third sub-pixel, and in the second pixel, the third color conversion layer may be disposed in the first sub-pixel and the first color conversion layer may be disposed in the third sub-pixel.

According to embodiments of the invention, a display device includes a first pixel which includes a first sub-pixel, a second sub-pixel, a third sub-pixel, and a fourth sub-pixel and in which a black matrix is disposed on at least one of the sub-pixels, in which the black matrix is disposed in one of the first sub-pixel to the fourth sub-pixel, and a color conversion layer disposed in the sub-pixel on which the black matrix is disposed is further disposed in another sub-pixel on which the black matrix is not disposed.

In the display device according to embodiments of the invention, the black matrix may be disposed in the first sub-pixel, and the color conversion layer of the first sub-pixel may be further disposed in the second sub-pixel.

In the display device according to embodiments of the invention, the black matrix may be disposed in the third sub-pixel, and the color conversion layer of the third sub-pixel may be further disposed in the fourth sub-pixel.

In the display device according to embodiments of the invention, the pixel can be repaired by repairing the color conversion layer.

In the display device according to embodiments of the invention, the image quality of the display panel can be improved by repairing the pixel.

In the display device according to embodiments of the invention, low power consumption can be achieved by repairing the sub-pixel.

In the display device according to embodiments of the invention, the structure of each sub-pixel can be optimized based on required current in the display device to which the sub-pixel repair may be applied.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A display device comprising:
a first pixel including a first sub-pixel, a second sub-pixel, a third sub-pixel, and a fourth sub-pixel;
a black matrix disposed on at least one of the first sub-pixel to the fourth sub-pixel of the first pixel; and
a second pixel disposed adjacent to the first pixel and including a first sub-pixel, a second sub-pixel, a third sub-pixel, and a fourth sub-pixel,
wherein, in the first pixel, a first color conversion layer is disposed on the first sub-pixel, a second color conversion layer is disposed on the second sub-pixel, a third color conversion layer is disposed on the third sub-pixel, and a fourth color conversion layer is disposed on the fourth sub-pixel, and
wherein, in the second pixel, a color conversion layer different from the first, second, third, and fourth color conversion layers is disposed on at least one of the first sub-pixel, the second sub-pixel, the third sub-pixel, and the fourth sub-pixel.

2. The display device of claim 1, wherein, in the first pixel, the black matrix is disposed on the first sub-pixel and the second sub-pixel, and
wherein, in the second pixel, the third color conversion layer is disposed on the first sub-pixel and the first color conversion layer is disposed on the third sub-pixel.

3. The display device of claim 1, wherein, in the first pixel, the black matrix is disposed on the first sub-pixel and the fourth sub-pixel, and
wherein, in the second pixel, the third color conversion layer is disposed on the first sub-pixel and the first color conversion layer is disposed on the third sub-pixel.

4. The display device of claim 1, wherein, in the first pixel, the black matrix is disposed on the third sub-pixel and the fourth sub-pixel, and
wherein, in the second pixel, the third color conversion layer is disposed on the first sub-pixel and the first color conversion layer is disposed on the third sub-pixel.

5. The display device of claim 1, wherein, in the first pixel, the black matrix is disposed on the second sub-pixel and the third sub-pixel, and
wherein, in the second pixel, the third color conversion layer is disposed on the first sub-pixel and the first color conversion layer is disposed on the third sub-pixel.

6. A display device comprising:
a first pixel including a first sub-pixel, a second sub-pixel, a third sub-pixel, a fourth sub-pixel; and
a black matrix disposed on at least one of the first sub-pixel to the fourth sub-pixel,
wherein a color conversion layer of the at least one of the first sub-pixel to the fourth sub-pixel on which the black matrix is disposed is further disposed on a remaining one of the at least one of the first sub-pixel to the fourth sub-pixel on which the black matrix is not disposed.

7. The display device of claim 6, wherein the black matrix is disposed on the first sub-pixel, and
wherein the color conversion layer of the first sub-pixel is further disposed on the second sub-pixel.

8. The display device of claim 6, wherein the black matrix is disposed on the third sub-pixel, and
wherein a color conversion layer of the third sub-pixel is further disposed on the fourth sub-pixel.

9. A display device comprising:
a substrate including a first pixel comprising a first sub-pixel and a fourth sub-pixel;
a 1a transistor and a 1d transistor disposed on the substrate; and
a first light-emitting element disposed on the first sub-pixel and electrically connected to the 1a transistor; and
a fourth light-emitting element disposed on the fourth sub-pixel and electrically connected to the 1d transistor,
wherein:
each of the first light-emitting element and the fourth light-emitting element includes an inorganic light-emitting element;
the first sub-pixel is configured to emit first light or third light;
the fourth sub-pixel is configured to emit second light or the third light;
each of the 1a transistor and the 1d transistor comprises a driving transistor; and
a width of a 1a semiconductor layer of the 1a transistor is greater than a width of a 1d semiconductor layer of the 1d transistor.

10. The display device of claim 9, wherein a length of the 1a semiconductor layer is the same as a length of the 1d semiconductor layer.

11. The display device of claim 9, wherein:
the 1a transistor further includes a 1a gate electrode disposed on the 1a semiconductor layer;
the 1d transistor further includes a 1d gate electrode disposed on the 1d semiconductor layer; and
a width of the 1a gate electrode is greater than a width of the 1d gate electrode.

12. The display device of claim 11, further comprising:
a 2a transistor electrically connected to the 1a gate electrode; and
a 2d transistor electrically connected to the 1d gate electrode,
wherein a width of a 2a semiconductor layer of the 2a transistor is the same as a width of a 2d semiconductor layer of the 2d transistor.

13. The display device of claim 12, wherein a length of the 2a semiconductor layer is the same as a length of the 2d semiconductor layer.

14. The display device of claim 12, wherein each of the 2a transistor and the 2d transistor comprises a switching transistor.

15. The display device of claim 13, further comprising:
a second sub-pixel defined on the substrate;
a 1b transistor disposed on the substrate; and
a second light-emitting element electrically connected to the 1b transistor and disposed on the second sub-pixel,
wherein:
the second light-emitting element includes the inorganic light-emitting element;
the second sub-pixel is configured to emit a green light or a red light;
the 1b transistor comprises the driving transistor; and
a width of a 1b semiconductor layer of the 1b transistor is greater than a width of the 1d semiconductor layer.

16. The display device of claim 15, wherein the width of the 1b semiconductor layer is the same as the width of the 1a semiconductor layer.

17. The display device of claim 16, wherein the length of the 1b semiconductor layer is the same as the length of the 1a semiconductor layer.

18. The display device of claim 15, wherein the second sub-pixel is disposed at a left side of the first sub-pixel in a plan view, and the fourth sub-pixel is disposed below the first sub-pixel in a plan view.

19. The display device of claim 9, further comprising a second sub-pixel,
wherein a current required for driving the first sub-pixel is higher than a current required for driving the second sub-pixel and a current required for driving the fourth sub-pixel.

20. The display device of claim 19, further comprising a third sub-pixel,
wherein a current required for driving the first sub-pixel is higher than a current required for driving the second sub-pixel and a current required for driving the fourth sub-pixel, and
wherein the current required for driving the second sub-pixel is higher than a current required for driving the third sub-pixel.
